(19) United States
(12) Patent Application Publication
(10) Pub. No.: US 2022/0002903 A1
(43) Pub. Date: Jan. 6, 2022

(54) HEAT SHIELD DEVICE FOR SINGLE CRYSTAL PRODUCTION FURNACE, CONTROL METHOD THEREOF AND SINGLE CRYSTAL PRODUCTION FURNACE

(71) Applicants: Shanghai Institute of Microsystem and Information Technology, Chinese Academy of Sciences, Shanghai (CN); Zing Semiconductor Corporation, Shanghai (CN)

(72) Inventors: Zhongying Xue, Shanghai (CN); Minghao Li, Shanghai (CN); Xing Wei, Shanghai (CN); Zhan Li, Shanghai (CN); Tao Wei, Shanghai (CN); Yun Liu, Shanghai (CN)

(21) Appl. No.: 17/139,990

(22) Filed: Dec. 31, 2020

(30) Foreign Application Priority Data
Jul. 1, 2020 (CN) 202010621682.3

(51) Int. Cl. C30B 15/20; C30B 29/06; C30B 15/14

(52) U.S. Cl. CPC C30B 15/20; C30B 15/14; C30B 29/06

(57) ABSTRACT

Disclosed a heat shield device for a single crystal production furnace. The heat shield device is disposed above a melt crucible of the single crystal production furnace, and comprises a shell, supporting members, heat insulation plates and a direction control component. The supporting members and the heat insulation plates are disposed within of the shell. One end of the supporting member is fixedly connected with an inner wall of the shell. The direction control component is connected with the heat insulation plate. The supporting members serve as supporting points of the heat insulation plates, and cooperate with the direction control component to control rotation of the heat insulation plates relative to the shell. A rotatable angle of the heat insulation plate faces a cylindrical surface of monocrystalline silicon, and a bottom surface of the shell faces interior of the melt crucible.

### CROSS REFERENCE TO RELATED APPLICATIONS

The present application claims the benefit of Chinese Patent Application No. 202010621682.3 filed on Jul. 1, 2020, the contents of which are incorporated herein by reference in their entirety.

### TECHNICAL FIELD

The present invention relates to the field of manufacturing equipment of semiconductors, and in particular to a heat shield device for a single crystal production furnace, a control method and a single crystal production furnace.

### BACKGROUND

Monocrystalline silicon plays an irreplaceable role as a material basis for sustainable development of industries of modern communication technology, integrated circuits, solar cells, and so on. At present, main methods for growing monocrystalline silicon from melt include the Czochralski method and the zone melting method. The Czochralski method for growing monocrystalline silicon has advantages of simple equipment and processes, easy to achieve automatic control, high production efficiency, easy preparation of a large-diameter monocrystalline silicon, as well as fast crystal growth, high crystal purity and high integrity, so that the Czochralski method has been rapidly developed.

To produce monocrystalline silicon in a single crystal production furnace using the Czochralski method, common silicon materials need to be melted and then recrystallized. According to the crystallization law of monocrystalline silicon, a raw material is heated and melted in a crucible, with a temperature controlled to be slightly higher than a crystallization temperature of silicon single crystal, to ensure that the molten raw material can be crystallized on the surface of the solution. The crystallized single crystal is pulled out of the liquid level through a pulling system of the Czochralski furnace, cooled and shaped under the protection of an inert gas, and finally crystallized into a crystal with a cylindrical body and a cone tail.

Monocrystalline silicon is grown in the heat field of the single crystal furnace, and thus the quality of the heat field significantly influences the growth and quality of the monocrystalline silicon. A good heat field can not only allow a single crystal to grow successfully, but also produce a high-quality single crystal. When heat field conditions are not sufficient, a single crystal may not be grown, and even though a single crystal is grown, the single crystal may be transformed to a polycrystal or has a structure with a large number of defects due to crystal transformation. Therefore, it is a very critical technology in a Czochralski monocrystalline silicon growth process to find better conditions and best configuration of the heat field.

In the design of an entire heat field, the most critical is the design of a heat shield. Firstly, the design of the heat shield directly influences the vertical temperature gradient of the solid-liquid interface, and determines the crystal quality by influencing a V/G ratio with changed temperatures. Secondly, the design of the heat shield will influence the horizontal temperature gradient of the solid-liquid interface, and control the quality uniformity of the entire silicon wafer. Finally, a properly designed heat shield will influence the heat history of the crystal, and control nucleation and growth of defects inside the crystal. Therefore, the design of the heat shield is very critical in the process of preparing high-grade silicon wafers.

At present, an outer layer of a commonly used heat shield is a SiC coating layer or pyrolytic graphite, and an inner layer the commonly used heat shield heat-insulating graphite felt. The heat shield which is cylindric is positioned in an upper portion of the heat field. A crystal bar is pulled out of the cylindric heat shield. The graphite of the heat shield which is close to the crystal bar has a lower heat reflectivity and absorbs heat emitted from the crystal bar. The graphite on the outside surface of the heat shield usually has a higher heat reflectivity, which is beneficial to reflect back the heat emitted from the melt, thereby improving the heat insulation performance for the heat field and reducing power consumption of the whole process. However, the existing heat shields still have the defect of non-uniform temperature gradient. Therefore, a heat field device for a single crystal production furnace and a single crystal production furnace, which are capable of dynamically controlling the temperature gradients, are needed.

### SUMMARY

An objective of the present invention is to provide a heat shield device for a single crystal production furnace, a control method, and a single crystal production furnace, to realize dynamic control of temperature gradients by changing the heat field design and controlling directions and angles of the heat insulation plates, thereby controlling the pulling rate.

In order to overcome the abovementioned problems in the prior art, the present invention can be achieved by the following technical solutions.

A heat shield device for a single crystal production furnace is disposed above a melt crucible of a single crystal production furnace, and comprises a shell, supporting members, heat insulation plates and a direction control component; the supporting members and the heat insulation plates are disposed within the shell, and one end of the supporting member is fixedly connected with an inner wall of the shell; the direction control component is connected with the heat insulation plates; the supporting members serve as supporting points of the heat insulation plates and cooperate with the direction control component to control rotation of the heat insulation plates relative to the shell; a rotatable angle of the heat insulation plate faces a cylindrical surface of monocrystalline silicon, and a bottom outside surface of the shell faces interior of the melt crucible.

In a preferred embodiment, an outer housing is further provided, the shell is disposed within the outer housing and at a bottom of the outer housing, and a space between the outer housing and the shell is filled with a heat insulation material.

In a preferred embodiment, a plurality of heat insulation plates are disposed within the shell, and there is one or two supporting members provided correspondingly for each of the heat insulation plates. Preferably, the supporting member is made of a graphite material.

In a preferred embodiment, a heat absorbing plate is further provided, a side face of the heat absorbing plate is connected with an inner wall of a bottom of the shell.

In a preferred embodiment, a proportion of a maximum projected area of the heat insulation plate on a bottom of the shell to a bottom area of the shell is in a range from 60% to 90%.

In a preferred embodiment, a controller, a motor and a transmission device are further provided; the controller is electrically connected with the motor, and the motor is connected with the direction control component via the transmission device.

In a preferred embodiment, the heat insulation plate at least comprises a heat insulation film assembly, and the heat insulation film assembly comprises a first refractive layer having first refractivity and a second refractive layer having second refractivity which is different from the first refractivity.

In a preferred embodiment, a plurality of temperature sensors and a temperature gradient computing unit are further provided; the plurality of temperature sensors are used to measure temperatures of an outer side surface of the monocrystalline silicon and are electrically connected with the temperature gradient computing unit, and the temperature gradient computing unit is electrically connected with the controller.

A control method of a heat shield device for a single crystal production furnace according to the present invention, which is used to control the heat shield device for a single crystal production furnace above, includes the following steps:

acquiring a temperature gradient on an outer side surface of monocrystalline silicon and a preset value;

determining whether the temperature gradient on the outer side surface of the monocrystalline silicon is equal to the preset value;

if YES, controlling heat insulation plates to be at a horizontal position; and

if NO, determining whether the temperature gradient on the outer side surface of the monocrystalline silicon is greater than the preset value;

if YES, controlling the heat insulation plate to be in a heat dissipation mode, and the heat dissipation mode means that a height of one end of the heat insulation plate close to the monocrystalline silicon from a horizontal plane is smaller than a height of one end of the heat insulation plate away from the monocrystalline silicon from the horizontal plane; and

if NO, controlling the heat insulation plate to be in a heating mode, the heating mode means that the height of one end of the heat insulation plate close to the monocrystalline silicon from the horizontal plane is greater than the height of one end of the heat insulation plate away from the monocrystalline silicon from the horizontal plane.

A single crystal production furnace according to the present invention comprises: a furnace body including a furnace body wall and an accommodation cavity enclosed by the furnace body wall; a melt crucible disposed within the accommodation cavity and for containing melt; a heater disposed within the accommodation cavity and around the melt crucible, and suitable for providing a heat field of the melt crucible; and a heat shield device for a single crystal production furnace above, a bottom outer surface of an outer housing faces interior of the melt crucible.

From the specific embodiments of the present invention, the present invention has the following beneficial effects:

(1) In the heat shield device for a single crystal production furnace and the single crystal production furnace according to the present invention, structure design of the existing heat shield is changed, the directions and angles of the heat insulation plates are controlled, and the flow direction of heat is changed by changing the flow channel of the heat, so that dynamic control of the temperature gradients are realized, thereby realizing control of the pulling rate;

(2) Information of the temperature gradient of the outer surface of monocrystalline silicon is collected, and the directions and angles of the heat insulation plates are controlled based on the temperature gradient of the outer surface of the monocrystalline silicon and the preset value, thereby realizing dynamic control of the temperature gradient;

(3) By using the heat insulation plate composed of at least two refractive layers with different refractivity, the heat emitted from the melt will be reflected to the periphery of the monocrystalline silicon or towards a direction away from the outer surface of the monocrystalline silicon, so that the heat insulation plate having such structure has higher heat reflection efficiency, which is conducive to optimizing of the radial temperature gradient of the monocrystalline silicon;

(4) The radial temperature gradient of the monocrystalline silicon is optimized by providing a shell and an outer housing and their cooperation with the heat insulation plate, while the longitudinal temperature gradient can also be optimized by filling the space between the outer housing and the shell with a heat insulation material; and

(5) The heat absorbing plate is further provided for collecting the heat emitted from the melt, thereby improving heat transmission efficiency.

### BRIEF DESCRIPTION OF DRAWINGS

In order to more clearly illustrate the technical solutions of the present invention, the accompanying drawings that are used in the description of the embodiments or the prior art will be briefly introduced hereafter. Obviously, the accompanying drawings in the following description are only some embodiments of the present invention, and other accompanying drawings can be obtained based on these drawings by those of ordinary skill in the art without creative work.

FIG. 1 is a partial section view showing a heat insulation plate of a heat shield device for a single crystal production furnace according to Embodiment 1 of the present invention inclining to one direction.

FIG. 2 is partial section view showing a heat insulation plate of a heat shield device for a single crystal production furnace according to Embodiment 1 of the present invention inclining to another direction.

FIG. 3 is a partial section view of a heat shield device for a single crystal production furnace according to Embodiment 2 of the present invention.

FIG. 4 is a block diagram showing a principle of a heat shield device for a single crystal production furnace according to the present invention.

FIG. 5 is a schematic structural diagram of a thin-plate heat insulation plate of a heat shield device for a single crystal production furnace according to the present invention.

FIG. 6 is a schematic structural diagram of a heat insulation plate in a form of a composite heat insulation layer of a heat shield device for a single crystal production furnace according to the present invention.

FIG. 7 is a flowchart showing a control method of a heat shield device for a single crystal production furnace according to the present invention.

FIG. 8 is a schematic structural diagram of a single crystal production furnace according to the present invention.

FIG. 9 is a partial section view of a heat shield device for a single crystal production furnace according to Embodiment 4 or 7 of the present invention.

### REFERENCE SIGNS ARE LISTED AS FOLLOWS

1—Shell, 2—Supporting member, 3—Heat insulation plate, 4—Direction control component, 5—Outer housing, 6—Heat insulation material, 7—Heat absorbing plate, 8—Controller, 9—Temperature sensor, 10—Temperature gradient computing unit, 11—First refractive layer, 12—Second refractive layer, 13—Supporting layer, 14—Monocrystalline silicon, 15—Melt crucible, 16—Heat shield device, and 17—Motor.

### DETAILED DESCRIPTION

Hereafter, the technical solutions according to embodiments of the present invention will be described clearly and thoroughly with reference to accompanying drawings. Obviously, the described embodiments are only part of, not all of, the embodiments of the present invention. Based on the embodiments of the present invention, all other embodiments obtained by those of ordinary skill in the art without creative work shall fall within the protection scope of the present invention.

An objective of the present invention is to provide a heat shield device for a single crystal production furnace, a control method, and a single crystal production furnace, to realize dynamic control of temperature gradients by changing the heat field design and controlling directions and angles of the heat insulation plates, thereby controlling the pulling rate.

In order to understand the above objective, features and advantages of the present invention clearer and easier, the present invention will be further illustrated below with reference to the drawings and the embodiments.

### Embodiment 1

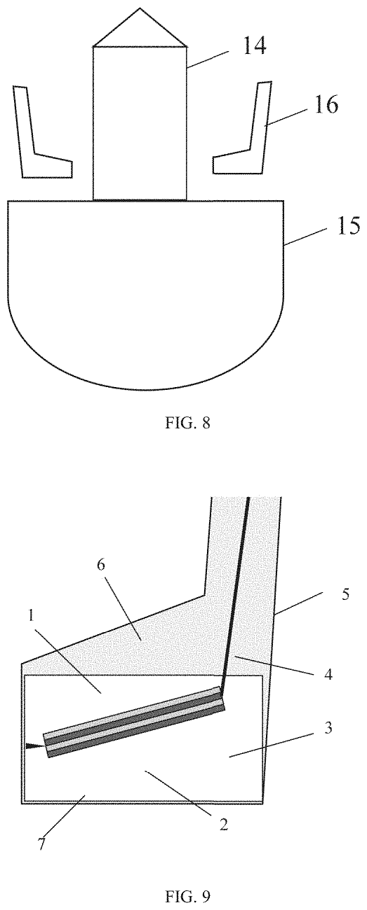

Refer to FIGS. 1, 2 and 8. A heat shield device for a single crystal production furnace is provided in the embodiment. The heat shield device 16 is disposed above a melt crucible 15 of a single crystal production furnace and comprises a shell 1, supporting members 2, heat insulation plates 3 and a direction control component 4. The supporting members 2 and the heat insulation plates 3 are disposed within the shell 1. One end of the supporting member 2 is fixedly connected with an inner wall of the shell 1. The direction control component 4 is connected with the heat insulation plates 3. The supporting members 2 serve as supporting points of the heat insulation plates 3, and cooperate with the direction control component 4 to control rotation of the heat insulation plates 3 relative to the shell 1. A rotatable angle of the heat insulation plate 3 faces a cylindrical surface of monocrystalline silicon 14, and a bottom outside surface of the shell 1 faces interior of the melt crucible 15. The supporting function of the supporting members 2 is to serve as supporting points of the heat insulation plates 3 so as to realize relative rotation of the heat insulation plates 3, so that the rotation direction of the heat insulation plates 3 can be both positive and negative. The heat shield device for a single crystal production furnace provided in the present invention has a simple structure, and changes structure design of the existing heat shield, controls the directions and angles of the heat insulation plates by means of the supporting members and the direction control component, changes the flow direction of heat by changing a flow channel of the heat, thereby realizing dynamic control of the temperature gradient and further realizing control of the pulling rate.

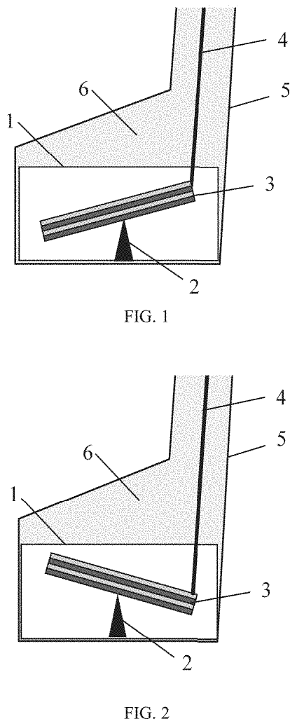

Furthermore, in the embodiment, the shell 1 has a ring structure with a cavity. The heat insulation plate 3 is in a fan ring shape, and there are two heat insulation plates 3. The two heat insulation plates each have a fan-shaped central angle of 180° and are disposed within the shell 1. When the two heat insulation plates are in a horizontal state, they are located in the same horizontal plane and do not overlap with each other. There is one supporting member provided correspondingly for each of the heat insulation plate 3. That is, there are two supporting members in all. A contact point where one end of the supporting member 2 contacting the heat insulation plate 3 is a supporting point of the heat insulation plate 3, and this contact point is at a middle part of the lower surface of the heat insulation plate 3. The direction control component is provided with two connecting members which are respectively connected with one sides of the middle parts of the two heat insulation plates, as shown in FIGS. 1 to 2. A proportion of a maximum projected area of the heat insulation plates 3 on a bottom of the shell 1 to a bottom area of the shell 1 is in a range from 60% to 90%. That is, when the heat insulation plates 3 are in a horizontal position, the projected area of the heat insulation plates 3 on the bottom of the shell 1 to a bottom area of the shell 1 is maximum. The supporting members 2 cooperate with the direction control component 4 while the supporting members 2 serve as supporting points, so that the inclination angles and the inclination directions of the heat insulation plates 3 can be controlled through up-and-down movement of the direction control component 4.

Further, an outer housing 5 is also comprised. The shell 1 is disposed within the outer housing 5 and in a lower portion of the outer housing 5. A space between the outer housing 5 and the shell 1 is filled with a heat insulation material 6. The radial temperature gradient of the monocrystalline silicon is optimized by providing the shell and the outer housing and their cooperation with the heat insulation plate, while the longitudinal temperature gradient can also be optimized by filling the space between the outer housing and the shell with a heat insulation material.

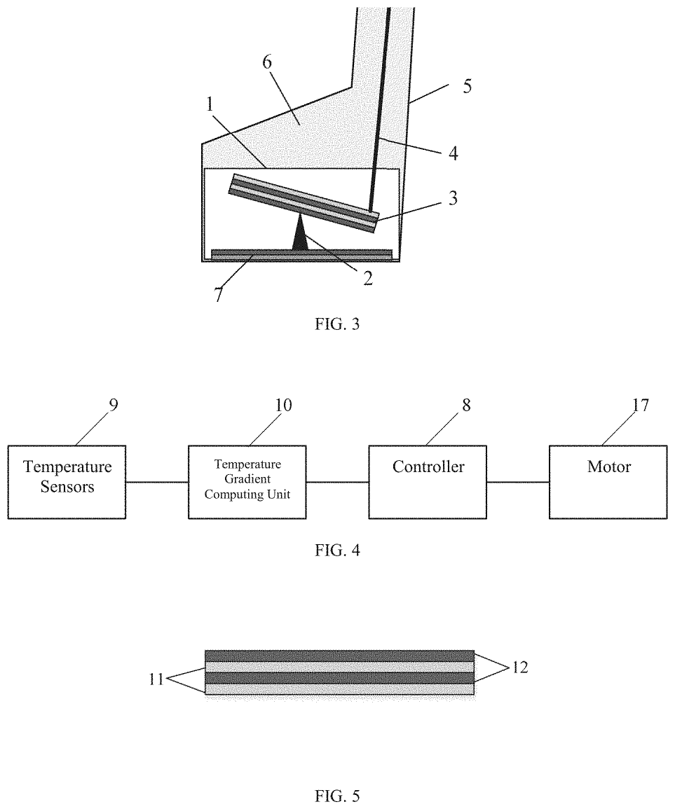

Further, as shown in FIG. 4, a controller 8, a motor 17 and a transmission device are also comprised. The controller 8 is electrically connected with the motor 17, and the motor 17 is connected with the direction control component 4 via the transmission device. Neither the connection relationship between the motor 17 and the transmission device nor the connection relationship between the transmission device and the direction control component 4 is shown in the drawings. The controller sends a control signal to the motor 17, and the motor 17 controls the movement of the direction control component 4 via the transmission device, thereby controlling the inclination directions and the inclination angles of the heat insulation plates. In the embodiment, the inclination angle of the heat insulation plate varies in a range from −30° to +30°. A plurality of temperature sensors 9 and a temperature gradient computing unit 10 are further comprised. The plurality of temperature sensors 9 are used to measure temperatures of an outer side surface of the monocrystalline silicon 14 and are electrically connected with the temperature gradient computing unit 10. The temperature gradient computing unit 10 is electrically connected with the controller 8. Temperature information of the outer surface of the monocrystalline silicon 14 is collected by the plurality of temperature sensors 9 and is transmitted to the temperature gradient computing unit 10 to calculate the temperature gradient, the calculated result of the temperature gradient is transmitted to the controller 8, so that real-time collection and monitoring of the temperature gradient of the outer surface of the monocrystalline silicon 14 can be realized.

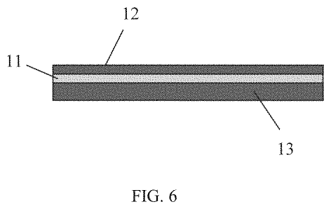

Further, in the embodiment, the heat insulation plate 3 includes two heat insulation film assemblies. The heat insulation film assembly comprises a first refractive layer 11 having first refractivity and a second refractive layer 12 having second refractivity which is different from the first refractivity. In other embodiments, for example as shown in FIG. 5, the heat insulation plate 3 may be a thin-plate heat insulation plate composed of a plurality of heat insulation film assemblies, or a thin-plate heat insulation plate composed of plurality of refractive layers with different refractivity. Or, for example as shown in FIG. 6, the heat insulation plate 3 may be a heat insulation plate in a form of a composite heat insulation layer composed of a supporting layer 13 and at least one heat insulation film assemble. Specifically, in the thin-plate heat insulation plate 3, the first refractive layer 11 is made of silicon or molybdenum, and the second refractive layer 12 is made of quartz. In the heat insulation plate 3 in a form of a composite heat insulation layer, the first refractive layer 11 is made of silicon, the second refractive layer 12 is made of quartz or silicon nitride, and the supporting layer 13 is made of silicon. The heat insulation plate 3 is composed of refractive layers with at least two different refractivity, so that the heat from the melt is reflected to the periphery of the monocrystalline silicon 14 or towards a direction away from the outer surface of the monocrystalline silicon 14. Therefore, the heat insulation plates 3 having such structure have higher heat reflection efficiency, which is beneficial for optimizing the radial temperature gradient of the monocrystalline silicon 14.

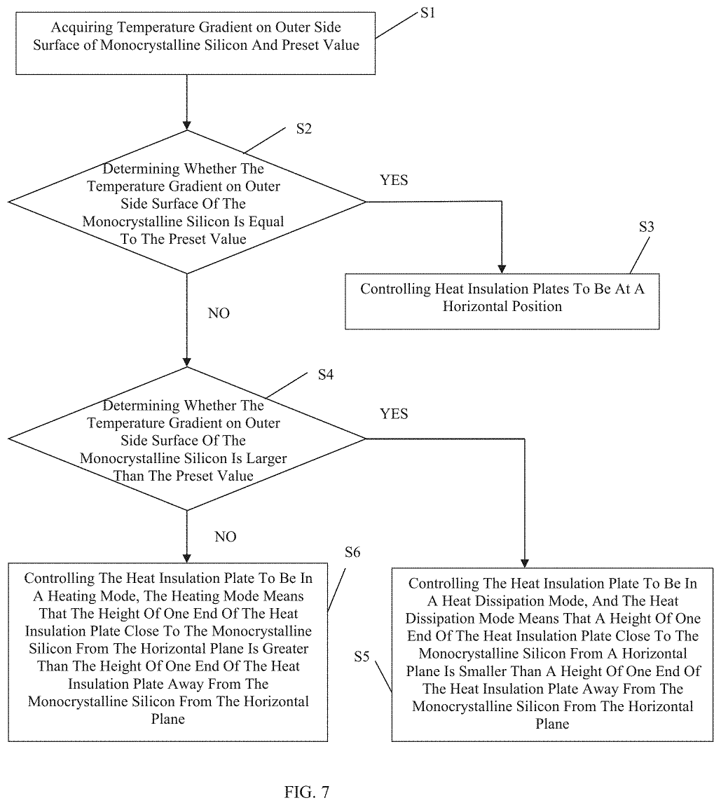

As shown in FIG. 7, a control method of a heat shield device for a single crystal production furnace according to the embodiment, which is used to control the heat shield device above, includes the following steps:

S1: acquiring a temperature gradient on an outer side surface of monocrystalline silicon and a preset value;

S2: determining whether the temperature gradient on the outer side surface of the monocrystalline silicon is equal to the preset value;

S3: if YES, controlling heat insulation plates to be at a horizontal position;

S4: if NO, determining whether the temperature gradient on the outer side surface of the monocrystalline silicon is greater than the preset value;

S5: if YES, controlling the heat insulation plate to be in a heat dissipation mode, and the heat dissipation mode means that a height of one end of the heat insulation plate close to the monocrystalline silicon from a horizontal plane is smaller than a height of one end of the heat insulation plate away from the monocrystalline silicon from the horizontal plane; and

S6: if NO, controlling the heat insulation plate to be in a heating mode, the heating mode means that the height of one end of the heat insulation plate close to the monocrystalline silicon from the horizontal plane is greater than the height of one end of the heat insulation plate away from the monocrystalline silicon from the horizontal plane.

Based on temperature information of the outer surface of the monocrystalline silicon 14 as collected by the temperature sensors 9, the temperature gradient computing unit 10 is used to calculate the temperature gradient of the outer surface of the monocrystalline silicon, then the temperature gradient is compared with a preset value. The directions and angles of the heat insulation plates 3 are controlled according to the comparison result, thereby realizing dynamic control of the temperature gradient.

### Embodiment 2

The difference of Embodiment 2 from Embodiment 1 is that a heat absorbing plate is additionally provided. As shown in FIG. 3, a heat shield device for a single crystal production furnace is provided in the embodiment. The heat shield device 16 is disposed above a melt crucible 15 of a single crystal production furnace and comprises a shell 1, supporting members 2, heat insulation plates 3 and a direction control component 4. The supporting members 2 and the heat insulation plates 3 are disposed within the shell 1. One end of the supporting member 4 is fixedly connected with an inner wall of the shell, and the direction control component 4 is connected with the heat insulation plates 3. The supporting members 2 serve as supporting points of the heat insulation plates 3, and cooperate with the direction control component 4 to control rotation of the heat insulation plates 3 relative to the shell 1. A rotatable angle of the heat insulation plate 3 faces a cylindrical surface of monocrystalline silicon 14, and a bottom outer surface of the shell 1 faces interior of the melt crucible 15. A heat absorbing plate 7 is further included, and a side face of the heat absorbing plate 7 is connected with an inner wall of a bottom of the shell 1. The heat absorbing plate is made of an absorptive composite material. Refractivity can be changed by changing the thickness or layer number of a thin film material, which causes different heat absorbing or insulation performance. The heat absorbing plate 7 is additionally provided to collect the heat emitted from the melt, thereby enhancing the efficiency of heat transmission.

### Embodiment 3

The difference of Embodiment 3 from Embodiment 1 is that the number and position of the supporting members 2, as well as the position of the direction control component are different. In Embodiment 3, the shell 1 has a ring structure provided with a cavity, the heat insulation plate 3 is in a fan ring shape, and there are two heat insulation plates 3, each of which has a fan-shaped central angle of 180° and is disposed within the shell 1. When the two heat insulation plates are both in a horizontal state, they are located in the same horizontal plane and do not overlap with each other. There are two supporting members provided correspondingly for each of the heat insulation plates 3. That is, there are four supporting members in all. A contact point where one end of the supporting member 2 contacting the heat insulation plate 3 is a supporting point of the heat insulation plate 3, and this contact point may be on an upper or lower surface of the heat insulation plate 3. The two supporting members 2 for each heat insulation plate 3 are provided at both side of a central axis of a fan-ring surface of the heat insulation plate 3, and the connection point of the direction control component 4 and the heat insulation plate 3 is between the two supporting members. A proportion of a maximum projected area of the heat insulation plates 3 on a bottom of the shell 1 to a bottom area of the shell 1 is in a range from 60% to 90%. The supporting members 2 cooperate with the direction control component 4 while the supporting members 2 serve as supporting points, so that the inclination angles and the inclination directions of the heat insulation plates 3 can be controlled by means of up-and-down movement of the direction control component 4.

### Embodiment 4

The difference of Embodiment 4 from the above embodiments is that the number and position of the supporting members 2, as well as the position of the direction control component are different. In Embodiment 4, there are two heat insulation plates 3 disposed within the shell 1, each in a fan ring shape. When the two heat insulation plates are both in a horizontal state, they are located in the same horizontal plane and do not overlap with each other. The heat insulation plate 3 has a fan-shaped central angle of 180°. There is one supporting member provided correspondingly for each heat insulation plate 3, and the supporting member cooperates with the direction control component 4 to control rotation of the heat insulation plate 3. The contact point of the supporting member 2 and the heat insulation plate 3 is at the middle of an upper or lower surface of the heat insulation plate 3. The direction control component is provided with four connecting members which are connected to the heat insulation plates in pairs and connected to two sides of the supporting member 2 respectively. The supporting members 2 cooperate with the direction control component 4 while the supporting members 2 serve as supporting points, so that the inclination angles and the inclination directions of the heat insulation plates 3 can be controlled by means of up-and-down movement of the direction control component 4.

### Embodiment 5

The difference of Embodiment 5 from the above embodiments is that the number and position of the supporting members 2, as well as the position of the direction control component are different. In Embodiment 5, there are three or more heat insulation plates 3, each in a fan ring shape, provided within the shell 1. When the heat insulation plates are all in a horizontal state, they are located in the same horizontal plane and two adjacent heat insulation plates do not overlap with each other. The numbers of the supporting members 2 and the connecting members of the direction control component 4 are equal to the number of the heat insulation plates 3. Each of the heat insulation plates 3 cooperates with one supporting member and a single connecting member of the direction control component 4. The contact point of the supporting member 2 and the heat insulation plate 3 is at the middle of the outer surface of the heat insulation plate 3 in a fan ring shape and is close to an inner ring side of the heat insulation plate 3 in a fan ring shape, or the contact point is at the middle of a side face of the heat insulation plate 3 close to the monocrystalline silicon 14 (as shown in FIG. 9). The connect point between the connecting member of the direction control component 4 and the heat insulation plate 3 is at the middle of the outer surface of the heat insulation plate 3 in a fan ring shape and is close to an outer ring side of the heat insulation plate 3 in a fan ring shape.

### Embodiment 6

The difference of Embodiment 6 from the above embodiments is that the number of the heat insulation plates 3 is different. In Embodiment 6, there are three or more heat insulation plates 3, each in a fan ring shape, provided within the shell 1. The heat insulation plates 3 each have the same fan-shaped central angle. When the heat insulation plates are all in a horizontal state, they are located in the same horizontal plane and two adjacent heat insulation plates 3 do not overlap with each other. The sum of the fan-shaped central angles of the heat insulation plates 3 is 360°. The heat insulation plates 3 are each provided with a supporting member 2 as a supporting point, and the supporting members 2 cooperate with the direction control component 4 to control rotation of the heat insulation plates 3. The contact point of the supporting member 2 and the heat insulation plate 3 is at the middle of an upper or lower surface of the heat insulation plate 3. The heat insulation plates 3 are each connected with two connecting members of the direction control component 4 and are respectively connected at both sides of each of the supporting member 2. The supporting members 2 cooperate with the direction control component 4 while the supporting members 2 serve as supporting points, so that the inclination angles and the inclination directions of the heat insulation plates 3 can be controlled by means of up-and-down movement of the direction control component 4.

### Embodiment 7

The difference of Embodiment 7 from Embodiment 6 is that the number and position of the supporting members 2, as well as the position of the direction control component are different. In Embodiment 7, there are three or more heat insulation plates 3, each in a fan ring shape, provided within the shell 1. The heat insulation plates 3 each have the same fan-shaped central angle. When the heat insulation plates are all in a horizontal state, they are located in the same horizontal plane and two adjacent heat insulation plates 3 do not overlap with each other. The sum of the fan-shaped central angles of the heat insulation plates 3 is 360°. The heat insulation plates 3 are each provided with two supporting members 2 as supporting points, and the supporting members 2 cooperate with the direction control component 4 to control rotation of the heat insulation plates 3. Two supporting member 2 for each heat insulation plate 3 are provided at two sides of a central axis of a fan-ring surface of the heat insulation plate 3, and the connecting point of the direction control component 4 with the heat insulation plate 3 is between the two supporting members. The supporting members 2 cooperate with the direction control component 4 while the supporting members 2 serve as supporting points, so that the inclination angles and the inclination directions of the heat insulation plates 3 can be controlled by means of up-and-down movement of the direction control component 4.

### Embodiment 8

The difference of Embodiment 8 from the above embodiments is that the shape of the heat insulation plate is different. In Embodiment 8, the heat insulation plates is in a square shape, and there are six or more heat insulation plates evenly disposed within the shell 1. When the heat insulation plates are all in a horizontal state, they are located in the same horizontal plane, and two adjacent heat insulation plates 3 do not overlap with each other. The numbers of the supporting members 2 and the connecting members of the direction control component 4 equal to the number of the heat insulation plates 3. Each of the heat insulation plates 3 cooperates with one supporting member and a single connecting member of the direction control component 4. The contact point of the supporting member 2 and the heat insulation plate 3 is at the middle of the outer surface of the heat insulation plate 3 in a fan ring shape and is close to an inner ring side of the heat insulation plate 3 in a fan ring shape, or the contact point is at the middle of a side face of the heat insulation plate 3 close to the monocrystalline silicon 14 (as shown in FIG. 9). The connect point between the connecting member of the direction control component 4 and the heat insulation plate 3 is at the middle of the outer surface of the heat insulation plate 3 in a fan ring shape and is close to an outer ring side of the heat insulation plate 3 in a fan ring shape.

The working principle of the heat shield device in the present invention is as follows: after the heat emitted from the melt is absorbed by the heat absorbing plate 7, the position of the heat insulation plates 3 is changed to form two different heat channels: as shown in FIG. 1, when the acute angle between the heat insulation plate 3 and the horizontal plane faces a direction away from the monocrystalline silicon 14, the heat is transferred by the heat insulation plates 3 towards a direction away from the monocrystalline silicon 14, which block the heat transfer towards the monocrystalline silicon 14, so that the outer surface temperature of the monocrystalline silicon is relatively reduced; as shown in FIG. 2, when the acute angle between the heat insulation plate 3 and the horizontal plane faces a direction close to the monocrystalline silicon 14, the heat is transferred by the heat insulation plates 3 towards a direction close to the monocrystalline silicon 14, so that the outer surface temperature of the monocrystalline silicon is relatively increased. The flow direction of heat is changed by changing the flow channel of the heat, thereby realizing dynamic control of the temperature gradient and further realizing control of the pulling rate.

The present invention has the following technical effects:

(1) In the heat shield device for a single crystal production furnace with a simple structure and the single crystal production furnace according to the present invention, structure design of the existing heat shield is changed, the directions and angles of the heat insulation plates are controlled, and the flow direction of heat is changed by changing the flow channel of the heat, so that dynamic control of the temperature gradients are realized, thereby realizing control of the pulling rate;

(2) Information of the temperature gradient of the outer surface of monocrystalline silicon is collected, and the directions and angles of the heat insulation plates are controlled based on the temperature gradient of the outer surface of the monocrystalline silicon and the preset value, thereby realizing dynamic control of the temperature gradient;

(3) By using the heat insulation plate composed of at least two refractive layers with different refractivity, the heat emitted from the melt will be reflected to the periphery of the monocrystalline silicon or towards a direction away from the outer surface of the monocrystalline silicon, so that the heat insulation plate having such structure has higher heat reflection efficiency, which is conducive to optimizing of the radial temperature gradient of the monocrystalline silicon;

(4) The radial temperature gradient of the monocrystalline silicon is optimized by providing a shell and an outer housing and their cooperation with the heat insulation plate, while the longitudinal temperature gradient can also be optimized by filling the space between the outer housing and the shell with a heat insulation material; and

(5) The heat absorbing plate is further provided for collecting the heat emitted from the melt, thereby improving heat transmission efficiency.

The principle and embodiments of the present invention are described herein with reference to specific embodiments, and the described of the above embodiments are only for better understanding of the method and the core concept of the present invention. Meanwhile, modifications can be made by those skilled in the art to the embodiments and application according to the spirit of the present invention. In a word, the content of the specification should not be understood as limits to the present invention.

1. A heat shield device for a single crystal production furnace, wherein the heat shield device for a single crystal production furnace (16) is disposed above a melt crucible (15) of a single crystal production furnace, and comprises a shell (1), supporting members (2), heat insulation plates (3) and a direction control component (4); the supporting members (2) and the heat insulation plates (3) are disposed within the shell (1), and one end of the supporting member (2) is fixedly connected with an inner wall of the shell; the direction control component (4) is connected with the heat insulation plates (3); the supporting members (2) serve as supporting points of the heat insulation plates (3) and cooperate with the direction control component (4) to control rotation of the heat insulation plates (3) relative to the shell (1); a rotatable angle of the heat insulation plate (3) faces a cylindrical surface of monocrystalline silicon (14), and a bottom outside surface of the shell (1) faces interior of the melt crucible (15).

2. The heat shield device for a single crystal production furnace according to claim 1, wherein an outer housing (5) is further provided, the shell (1) is disposed within the outer housing (5) and at a bottom of the outer housing (5), and a space between the outer housing (5) and the shell (1) is filled with a heat insulation material (6).

3. The heat shield device for a single crystal production furnace according to claim 1, wherein a plurality of heat insulation plates (3) are disposed within the shell (1), and there is one or two supporting members (2) provided correspondingly for each of the heat insulation plates (3).

4. The heat shield device for a single crystal production furnace according to claim 1, wherein a heat absorbing plate (7) is further provided, a side face of the heat absorbing plate (7) is connected with an inner wall of a bottom of the shell (1).

5. The heat shield device for a single crystal production furnace according to claim 1, wherein a proportion of a maximum projected area of the heat insulation plate (3) on a bottom of the shell (1) to a bottom area of the shell (1) is in a range from 60% to 90%.

6. The heat shield device for a single crystal production furnace according to claim 1, wherein a controller (8), a motor (17) and a transmission device are further provided; the controller (8) is electrically connected with the motor (17), and the motor (17) is connected with the direction control component (4) via the transmission device.

7. The heat shield device for a single crystal production furnace according to claim 1, wherein the heat insulation plate (3) at least comprises a heat insulation film assembly, and the heat insulation film assembly comprises a first refractive layer (11) having first refractivity and a second refractive layer (12) having second refractivity which is different from the first refractivity.

8. The heat shield device for a single crystal production furnace according to claim 6, wherein a plurality of temperature sensors (9) and a temperature gradient computing unit (10) are further provided; the plurality of temperature sensors (9) are used to measure temperatures of an outer side surface of the monocrystalline silicon (14) and are electrically connected with the temperature gradient computing unit (10), and the temperature gradient computing unit (10) is electrically connected with the controller (8).

9. A control method of a heat shield device for a single crystal production furnace, which is used to control the heat shield device for a single crystal production furnace according to claim 1, wherein the control method includes the following steps:
acquiring a temperature gradient on an outer side surface of monocrystalline silicon and a preset value;
determining whether the temperature gradient on the outer side surface of the monocrystalline silicon is equal to the preset value;
if YES, controlling heat insulation plates to be at a horizontal position; and
if NO, determining whether the temperature gradient on the outer side surface of the monocrystalline silicon is greater than the preset value;
if YES, controlling the heat insulation plate to be in a heat dissipation mode, and the heat dissipation mode means that a height of one end of the heat insulation plate close to the monocrystalline silicon from a horizontal plane is smaller than a height of one end of the heat insulation plate away from the monocrystalline silicon from the horizontal plane; and
if NO, controlling the heat insulation plate to be in a heating mode, the heating mode means that the height of one end of the heat insulation plate close to the monocrystalline silicon from the horizontal plane is greater than the height of one end of the heat insulation plate away from the monocrystalline silicon from the horizontal plane.

10. A single crystal production furnace, wherein the single crystal production furnace comprises:
a furnace body including a furnace body wall and an accommodation cavity enclosed by the furnace body wall;
a melt crucible (15) disposed within the accommodation cavity and for containing melt;
a heater disposed within the accommodation cavity and around the melt crucible (15), and suitable for providing a heat field of the melt crucible (15); and
a heat shield device for a single crystal production furnace according to claim 1, a bottom outer surface of an outer housing (5) faces interior of the melt crucible (15).

11. A control method of a heat shield device for a single crystal production furnace, which is used to control the heat shield device for a single crystal production furnace according to claim 2, wherein the control method includes the following steps:
acquiring a temperature gradient on an outer side surface of monocrystalline silicon and a preset value;
determining whether the temperature gradient on the outer side surface of the monocrystalline silicon is equal to the preset value;
if YES, controlling heat insulation plates to be at a horizontal position; and
if NO, determining whether the temperature gradient on the outer side surface of the monocrystalline silicon is greater than the preset value;
if YES, controlling the heat insulation plate to be in a heat dissipation mode, and the heat dissipation mode means that a height of one end of the heat insulation plate close to the monocrystalline silicon from a horizontal plane is smaller than a height of one end of the heat insulation plate away from the monocrystalline silicon from the horizontal plane; and
if NO, controlling the heat insulation plate to be in a heating mode, the heating mode means that the height of one end of the heat insulation plate close to the monocrystalline silicon from the horizontal plane is greater than the height of one end of the heat insulation plate away from the monocrystalline silicon from the horizontal plane.

12. A control method of a heat shield device for a single crystal production furnace, which is used to control the heat shield device for a single crystal production furnace according to claim 3, wherein the control method includes the following steps:
acquiring a temperature gradient on an outer side surface of monocrystalline silicon and a preset value;
determining whether the temperature gradient on the outer side surface of the monocrystalline silicon is equal to the preset value;
if YES, controlling heat insulation plates to be at a horizontal position; and
if NO, determining whether the temperature gradient on the outer side surface of the monocrystalline silicon is greater than the preset value;
if YES, controlling the heat insulation plate to be in a heat dissipation mode, and the heat dissipation mode means that a height of one end of the heat insulation plate close to the monocrystalline silicon from a horizontal plane is smaller than a height of one end of the heat insulation plate away from the monocrystalline silicon from the horizontal plane; and
if NO, controlling the heat insulation plate to be in a heating mode, the heating mode means that the height of one end of the heat insulation plate close to the monocrystalline silicon from the horizontal plane is greater than the height of one end of the heat insulation plate away from the monocrystalline silicon from the horizontal plane.

13. A control method of a heat shield device for a single crystal production furnace, which is used to control the heat shield device for a single crystal production furnace according to claim 4, wherein the control method includes the following steps:
acquiring a temperature gradient on an outer side surface of monocrystalline silicon and a preset value;
determining whether the temperature gradient on the outer side surface of the monocrystalline silicon is equal to the preset value;
if YES, controlling heat insulation plates to be at a horizontal position; and
if NO, determining whether the temperature gradient on the outer side surface of the monocrystalline silicon is greater than the preset value;
if YES, controlling the heat insulation plate to be in a heat dissipation mode, and the heat dissipation mode means that a height of one end of the heat insulation plate close to the monocrystalline silicon from a horizontal plane is smaller than a height of one end of the heat insulation plate away from the monocrystalline silicon from the horizontal plane; and
if NO, controlling the heat insulation plate to be in a heating mode, the heating mode means that the height of one end of the heat insulation plate close to the monocrystalline silicon from the horizontal plane is greater than the height of one end of the heat insulation plate away from the monocrystalline silicon from the horizontal plane.

14. A control method of a heat shield device for a single crystal production furnace, which is used to control the heat shield device for a single crystal production furnace according to claim 5, wherein the control method includes the following steps:
acquiring a temperature gradient on an outer side surface of monocrystalline silicon and a preset value;
determining whether the temperature gradient on the outer side surface of the monocrystalline silicon is equal to the preset value;
if YES, controlling heat insulation plates to be at a horizontal position; and
if NO, determining whether the temperature gradient on the outer side surface of the monocrystalline silicon is greater than the preset value;
if YES, controlling the heat insulation plate to be in a heat dissipation mode, and the heat dissipation mode means that a height of one end of the heat insulation plate close to the monocrystalline silicon from a horizontal plane is smaller than a height of one end of the heat insulation plate away from the monocrystalline silicon from the horizontal plane; and
if NO, controlling the heat insulation plate to be in a heating mode, the heating mode means that the height of one end of the heat insulation plate close to the monocrystalline silicon from the horizontal plane is greater than the height of one end of the heat insulation plate away from the monocrystalline silicon from the horizontal plane.

15. A control method of a heat shield device for a single crystal production furnace, which is used to control the heat shield device for a single crystal production furnace according to claim 6, wherein the control method includes the following steps:
acquiring a temperature gradient on an outer side surface of monocrystalline silicon and a preset value;
determining whether the temperature gradient on the outer side surface of the monocrystalline silicon is equal to the preset value;
if YES, controlling heat insulation plates to be at a horizontal position; and
if NO, determining whether the temperature gradient on the outer side surface of the monocrystalline silicon is greater than the preset value;
if YES, controlling the heat insulation plate to be in a heat dissipation mode, and the heat dissipation mode means that a height of one end of the heat insulation plate close to the monocrystalline silicon from a horizontal plane is smaller than a height of one end of the heat insulation plate away from the monocrystalline silicon from the horizontal plane; and
if NO, controlling the heat insulation plate to be in a heating mode, the heating mode means that the height of one end of the heat insulation plate close to the monocrystalline silicon from the horizontal plane is greater than the height of one end of the heat insulation plate away from the monocrystalline silicon from the horizontal plane.

16. A single crystal production furnace, wherein the single crystal production furnace comprises:
a furnace body including a furnace body wall and an accommodation cavity enclosed by the furnace body wall;
a melt crucible (15) disposed within the accommodation cavity and for containing melt;
a heater disposed within the accommodation cavity and around the melt crucible (15), and suitable for providing a heat field of the melt crucible (15); and
a heat shield device for a single crystal production furnace according to claim 2, a bottom outer surface of an outer housing (5) faces interior of the melt crucible (15).

17. A single crystal production furnace, wherein the single crystal production furnace comprises:
a furnace body including a furnace body wall and an accommodation cavity enclosed by the furnace body wall;
a melt crucible (15) disposed within the accommodation cavity and for containing melt;
a heater disposed within the accommodation cavity and around the melt crucible (15), and suitable for providing a heat field of the melt crucible (15); and
a heat shield device for a single crystal production furnace according to claim 3, a bottom outer surface of an outer housing (5) faces interior of the melt crucible (15).

18. A single crystal production furnace, wherein the single crystal production furnace comprises:
a furnace body including a furnace body wall and an accommodation cavity enclosed by the furnace body wall;
a melt crucible (15) disposed within the accommodation cavity and for containing melt;
a heater disposed within the accommodation cavity and around the melt crucible (15), and suitable for providing a heat field of the melt crucible (15); and
a heat shield device for a single crystal production furnace according to claim 4, a bottom outer surface of an outer housing (5) faces interior of the melt crucible (15).

19. A single crystal production furnace, wherein the single crystal production furnace comprises:
a furnace body including a furnace body wall and an accommodation cavity enclosed by the furnace body wall;
a melt crucible (15) disposed within the accommodation cavity and for containing melt;
a heater disposed within the accommodation cavity and around the melt crucible (15), and suitable for providing a heat field of the melt crucible (15); and
a heat shield device for a single crystal production furnace according to claim 5, a bottom outer surface of an outer housing (5) faces interior of the melt crucible (15).

20. A single crystal production furnace, wherein the single crystal production furnace comprises:
a furnace body including a furnace body wall and an accommodation cavity enclosed by the furnace body wall;
a melt crucible (15) disposed within the accommodation cavity and for containing melt;
a heater disposed within the accommodation cavity and around the melt crucible (15), and suitable for providing a heat field of the melt crucible (15); and
a heat shield device for a single crystal production furnace according to claim 6, a bottom outer surface of an outer housing (5) faces interior of the melt crucible (15).
